(19) United States
(12) Patent Application Publication
(10) Pub. No.: US 2007/0254208 A1
(43) Pub. Date: Nov. 1, 2007

(54) Method for Photo-Embossing a Monomer-Containing Layer

(75) Inventors: Ralph Kurt, Eindhoven (NL); Margaretha Maria De Kok-Van Breemen, Eindhoven (NL); Hans-Helmut Bechtel, Roetgen (DE); Sepas Setayesh, Eindhoven (NL); Dirk Jan Broer, Eindhoven (NL); Martin Jacobus Johan Jak, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONIC, N.V., EINDHOVEN (NL)

(21) Appl. No.: 10/596,317

(22) PCT Filed: Dec. 6, 2004
(86) PCT No.: PCT/IB04/52668

§ 371 Date: May 16, 2007

(30) Foreign Application Priority Data
Dec. 10, 2003 (EP) 03104615.4

(51) Int. Cl. H01L 31/00; H01J 1/62; H01M 10/02; H01M 4/02

(52) U.S. Cl. 429/126; 136/256; 313/483; 429/209; 430/322

(57) ABSTRACT

The invention relates to a method for photo-embossing a monomer-containing layer for obtaining a photovoltaic cell, a light emitting diode (LED), or a light emitting electrochemical cell (LEC) by the steps of: (a) optionally providing one or more layers onto the surface of the monomer-containing layer, (b) irradiating through a mask a layer consisting of a homogeneous blend of at least two different compounds, at least one of which is a polymerizable monomer, to obtain a monomer-containing layer with exposed and non-exposed areas; (c) optionally providing further layers onto the surface of the monomer-containing layer; (d) expanding the exposed or the non-exposed areas by diffusing at least one of the monomers to the exposed areas to obtain a corrugated surface of the layer; or interchanging steps c) and d).

The invention relates to a method for photo-embossing a monomer-containing layer for obtaining a photovoltaic cell, a light emitting diode (LED), or light emitting electrochemical cells (LEC), and to a photovoltaic cell, a LED or LEC comprising a corrugated layer.

Conductive polymer-based solar cells are known in the art. In U.S. Pat. No. 5,986,206 a solar cell is described comprising corrugated layers. The method for making such corrugated structures is only described in general terms, for instance the polymer film can be formed on a corrugated surface that serves as the support or as an electrode. A similar principle was also disclosed in U.S. Pat. No. 6,127,624 wherein prism-like layers are described in solar cells. This reference, however, is silent on the method to obtain such corrugated structures. In U.S. Pat. No. 4,554,727 a transparent conductor of a photovoltaic cell is corrugated (textured) by lithographic techniques. According to these techniques the transparent conductor was coated with an array of polymer spheres. These spheres were etched away by using an argon ion beam through a mask, and the polymer spheres were chemically removed. These prior art methods are either too general to be carried out or too complicated as a commercially available method for reproducibly forming corrugated layers. Further, the use of corrugated polymer layers in other type of cells, particularly in light emitting diode and light emitting electrochemical cells is unknown in the art. It is of considerable advantage to provide a general method of obtaining corrugated layers for use in various cells, i.e. not only in photovoltaic cells but also in layered stacks for use in LEDs (light emitting diodes), polyLEDs (polymeric light emitting diodes), OLEDs (organic light emitting diodes), smLEDs (small molecules light emitting diodes), LECs (light emitting electrochemical cells), and the like.

It is therefore an object of the invention to provide a simple, reproducible, and cheap method for making corrugated layers in cells. It is another object to provide a method that can be used for cells other than photovoltaic cells, such as light emitting diode cells (LED and OLED) and light emitting electrochemical cells (LEC). In the latter cases (LEDs and LECs) it is also an objective to mitigate if present the degradation of the light emitting polymer (LEP), the lifetime of which can be strongly reduced due to degradation, especially when the LEP emits blue light

To this end the present invention provides such method for photo-embossing a monomer-containing layer for obtaining a photovoltaic cell, a light emitting diode (LED), or a light emitting electrochemical cell (LEC) by the steps of:
(a) optionally providing one or more layers onto the surface of the monomer-containing layer;
(b) irradiating through a mask a layer consisting of a homogeneous blend of at least two different compounds, at least one of which is a polymerizable monomer, to obtain a monomer-containing layer with exposed and non-exposed areas;
(c) optionally providing further layers onto the surface of the monomer-containing layer;
(d) expanding the exposed or the non-exposed areas by diffusing at least one of the monomers to the exposed areas to obtain a corrugated surface of the layer;
   or interchanging steps c) and d).

State-of-the-art organic solar cells suffer from a very low overall quantum efficiency mainly due to the mismatch between the relative narrowband absorption characteristics of the active organic materials compared to the broadband of the entire solar spectrum. Most of the organic materials have a relatively small absorption coefficient at longer wavelengths. Combined with another limiting factor, which is the very thin layer thickness, it does not allow converting light with a longer wavelength efficiently.

The light path and the electrical (current) path through the optical active layer can be decoupled by shaping the active photovoltaic organic layer into a corrugated three-dimensional (3D) microstructure, while keeping the footprint and the layer thickness unchanged. This strongly increases the optical path length through the active photovoltaic layer and allows therefore higher conversion efficiencies also due to trapping the light into e.g. pyramid-like structures. In organic light emitting diode (OLED) displays (including polyLED and smOLED) and LECs, this leads to higher pixel brightness and/or reduced material degradation. Hot embossing methods have been described for OLEDs, see J. R. Lawrence et al., Applied Physics Letters, 81 (11), 2002, p. 1955-1957, and for organic solar cells, see L. S. Roman et al., Advanced Materials, 12 (3), 189 (2000). However, by using such methods only the upper surface of the active layer is embossed. In other words, the thickness of the active layer is not homogeneous. Various thicknesses in active layers lead to different electrical resistance. In LEDs and LECs this leads to light emitting processes in the areas with the lowest resistance. In photovoltaic cells such layers lead to light collection in the areas with the lowest resistance only. Thus only part of the cell is then used. In the cells of the invention the whole cell is used because the electrical resistance is constant over the whole area.

Additional advantages of the invention are i) reduced degradation (less light per molecule) of the light emitting electroluminescent layer or the photovoltaic layer (i.e. the active layer) and therefore longer lifetime, ii) better light-in (for solar cell) or light-out (for LED/LEC) coupling and light recycling (multiple reflection instead of single reflection), and iii) light-out-of-main-absorption-band also contributes to photocurrent in solar cells. The micro-structuring method of this invention allows generating 2D grating with a grating pitch smaller than the wavelength of the light to improve the performance of the cell even further (light trapping/photonic crystal).

Consequently, the absorption/conversion spectrum of such a device will lock much broader. Furthermore, the proposed solutions can be extended to introduce periodic or non-periodic structures on a sub-wavelength scale, to suppress the effect of surface plasmons and to increase the light-in (for solar cell) or light-out (for LED/LEC) coupling efficiency further, and additionally in OLEDs and LECs to suppress the wave-guiding effect of light.

In the creation of conjugated polymer photovoltaic devices, and LEDs and LECs, a limiting aspect of the device physics is the short diffusion length of excited states in conjugated polymers, typically in the range 5 to 20 nm. The harvesting in common organic materials is most effective for thicknesses up to 100±20 nm. The penetration depth of light into these materials has to be adapted correspondingly, i.e. strong optical absorption of the conjugated polymers (typically, in a relatively narrow absorption band) is required.

The dissociation of excited states, necessary for creating charge carriers, occurs at interfaces, impurities, or in strong electric fields. Efficient charge generation can occur if all exited states can find a dissociating site close enough; this is done in the distributed donor±acceptor networks based on combination of conjugated polymers and efficient acceptors such as use of asymmetric contacts of different work function gives a built-in electric field to separate the charge carriers and extract a photocurrent. By making thicker polymer layers, to collect more of the light by absorption the field is also decreased and the collection efficiency reduced, to compromise the photocurrent. It is therefore desirable to make very thin organic photovoltaic devices and find ways of enhancing the absorption in these polymer layers. Also OLEDs are typically very thin devices (the emissive layer is in the order of hundred nanometer) due to limited conductivity of the materials.

The invention provides an organic photovoltaic, LED or LEC device wherein the active layer is attached to a “rough” surface (on micrometer level or even less) whereas the active layer maintains its homogeneous photoelectrical properties characterized by a homogeneous thickness. Thus the upper and lower surfaces follow the corrugated first electrode layer. The “rough” surface microstructure, which is further defined as a corrugated structure, can be realized as an array of pyramids, toothed 2D- or 3D-structures, sinus- or wave-like gratings or folded foils, and the like. In fact the surface can be significantly increased. As a consequence the volume of the active (photovoltaic or LEP) layer also increases even when the thickness of the active layer remains unchanged. This allows for photovoltaic cells a broader absorption of the incident light, higher efficiency (due to the longer optical path, multiple reflection and light trapping) and for photovoltaic, LED and LEC cells improved lifetime (due to lowered material stress).

Apart from using pyramidal grating structures in LEDs and LECs, which also can be made by applying a known ITO sputtering technique, the surface of a substrate can also be shaped for instance as a dense array of pyramids by embossing techniques.

The embossing technique as such is known from a reference by C. de Witz and D. J. Broer, Photo-embossing as a tool for creating complex surface relief structures, Polymer Preprints (American Chemical Society, Div. Polymer Chemistry, 2003, 44(2), 236-237. This reference discloses the embossing technique without disclosing any practical application for said technique. The technique as described has now been found to be particularly useful for application in the present invention.

The essence of the invention is the provision of a layer consisting of a homogeneous blend of at least two different compounds, at least one of which is a polymerizable monomer, to obtain a monomer-containing layer. Preferably, one compound is a polymerizable monomer, whereas the other compound is a polymer. Suitable monomers contain acrylic or methacrylic moieties separated from each other by a spacer. The precise chemical nature of the spacer is not decisive for the invention, but for practical reasons aromatic groups, silicon oligomers, polyalkylene oligomers, fluorinated oligomers, and the like can be used. A typical example is mentioned in the Experimental part of the above-mentioned Witz article, which is incorporated by reference.

The following gives an example of how to practice the invention to realize enlarged emissive surface of organic solar cells (for transparent substrate=bottom excitation) and LEDs and LECs (for bottom emission).

On top of a print glass plate or other transparent substrate, optionally provided with means of addressing, ITO in the pixels, ISO walls for exact placement of droplets with, for instance, an ink jet process. In this manner for instance a 1-10 μm, preferably about 5 μm thick layer of the photo-embossing material is deposited, such as by an ink jet or screen printing technique. To allow sufficient electric contact the footprint of the underlying ITO layer is slightly larger than that of the printed polymer. The photo-embossing film containing the reactive component is composed such that, although it contains relatively low molecular weight monomer, it behaves as a solid state film, i.e. is virtually tack-free and can be handled as a solid state material for further processing. On top of the photo-embossed layer a thin ITO layer is deposited (or another anodic layer, which should be conductive as well as tansparent, e.g. PEDOT). Alternatively, no ITO layer is deposited but conductive components can be added to the blend. Subsequently, an optional hole injection layer such as PEDOT is deposited followed by a layer comprising a light emitting polymer (LEP). PEDOT and LEP may be deposited, for instance by a spin coating or ink jet printing technique, or the like. In another embodiment, the photo-embossing layer is first irradiated and thereafter ITO, LEP, and/or other layers are deposited thereon. Exposure, usually by UV irradiation, is performed through a mask to obtain the desired exposed and non-exposed areas in the photo-embossing layer. At the irradiated parts the reactive particles, in a preferred embodiment free radicals obtained by addition of a photo-initiator, are formed without any or only limited polymerization of the monomers. When the stack is subsequently heated, the monomer or monomers will diffuse to the UV irradiated area where they polymerize, thereby causing an increase of the local volume leading to deformation of the surface. The diffusion process can take place in various ways. Thus one of the monomers may diffuse to the exposed areas, whereas a second monomer or polymer does not diffuse. It is also possible that one monomer diffuses to the exposed areas and the other monomer or polymer diffuses to the non-exposed areas. In a third alternative two different monomers diffuse to the exposed areas.

The photovoltaic, LED or LEC cell has a photovoltaic or light emitting organic luminescent layer, for instance a light emitting polymeric (LEP) layer (the active layer), having a surface area being at least 30%, preferably 50 to 100%, greater that the planar projected area thereof. Thus a principle of the invention is that layers, such as LEP layers, are deposited as flat layers onto the photo-embossing layer. After the heat treatment the photo-embossing layer becomes corrugated, after which the originally flat layer or layers adopt said corrugated structure. In a particularly preferred embodiment examples of materials that can be used are pentaerythritol tetraacrylate (monomer) and poly(benzylmethacrylate) (polymer). The thermal treatment that induces the diffusion process of the monomers and the subsequent polymerization may be performed in one or more steps to develop the corrugated microstructure in the layer. For instance, a first step is performed at 80° C., after which the temperature is enhanced to 130° C., which temperature should preferably be slightly higher than the Tg of the LEP layer to allow the LEP layer to follow the structure of the corrugated layer. In a preferred embodiment for obtaining a bottom emission device, the invention pertains to LED or LEC cells wherein at least the substrate, the corrugated monomer-containing layer, and the first electrode layer are transparent. In yet another embodiment for obtaining a top emission LEP or LEC cell, the second electrode on top of the LEP layer is transparent as well as are layers optionally deposited on top for, e.g. protection and sealing purposes.

A cathode layer can be deposited onto the corrugated LEP layer in the usual manner, such as by sputtering or vacuum evaporation, and the like. Other layers, such a protective layers can also be deposited.

Conform thin layer deposition can be realized by evaporation or CVD in case of small molecule photovoltaic or LED/LEC. The embossing could be used to structure the surface of a photovoltaic, LED, or LEC device. In a preferred embodiment one of the layers of the LED or LEC is a reflective layer, for instance a reflective metal, to increase the contrast significantly. In a special embodiment of this invention, an electrode is used that can also serve as a reflective layer. The reflective layer is capable of reflecting light emitted in the active layer back towards the viewer. The LED or LEC of this invention are suitable for displays, including flat emissive displays. In the case of a photovoltaic cell according to the invention a reflecting layer is beneficial for allowing multiple reflection of light rays, enlarging the light path, thereby improving absorption and efficiency of the device.

To the skilled person it is further clear that it is not required that the complete cell has a corrugated structure. It is also possible that in LED and LEC displays only sub-pixels are corrugated, for instance only the blue pixels.

With the micro-structuring methods described herein it is also possible to generate 2D grating with a grating pitch smaller than the wavelength of the light to improve the performance even further (light trapping/photonic crystal).

The invention is further illustrated by the figures.

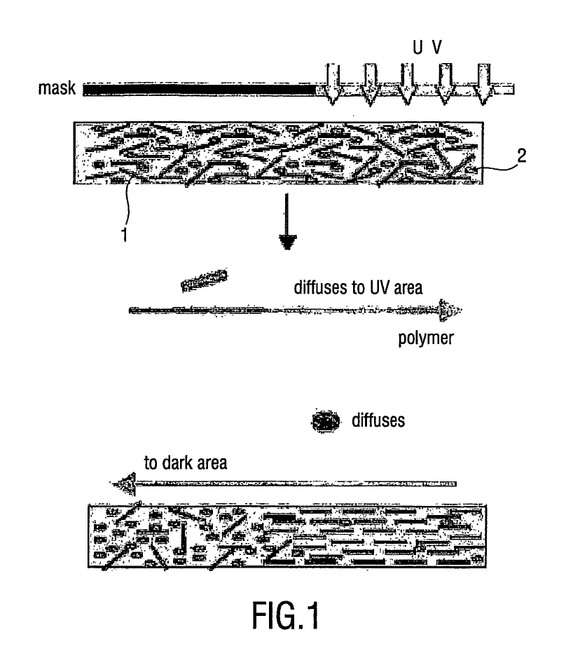

FIG. 1 shows a scheme of the embossing process according to the invention.

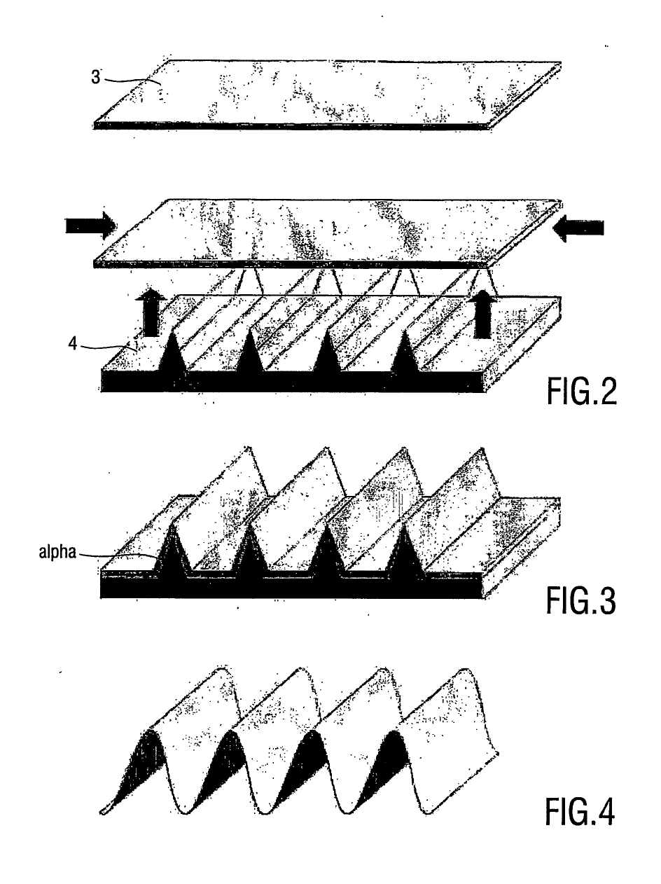

FIG. 2 shows the deposition of a LEP layer onto a corrugated surface.

FIG. 3 shows part of a pyramid-like LED or photovoltaic cell.

FIG. 4 shows another embodiment of the corrugated structure.

In FIG. 1 a homogeneous blend of two different polymerizable compounds, in this case monomers, is represented by rods 1 and ellipsoids 2. The layer is irradiated by UV light through a mask to obtain polymerization in the irradiated area. One of the monomers, herein rods 1, diff-uses to the irradiated area, whereas the ellipsoids 2 diffuse to the non-irradiated area After heat treatment the irradiated area expands relative to the non-irradiated area (not shown). Rods 1 can, for instance, may have the chemical formula: CH2═C(CH3)—CO—O—(CH2)3—[Si(CH3)2—O]3—Si(CH3)2—(CH2)3—O—CO—C(CH3)═CH2 or polybenzyl methacrylate. Ellipsoid 2, for instance, may have the chemical formula: CH2═CH—CO—O—C6H4—C(CF3)2—C6H4—O—CO—CH═CH2 or pentaerythritol acrylate. Other mixtures are for instance the mixture containing 60 parts of polymethyl methacrylate, 36 parts of trimethylol propane triacrylate, 2 parts of benzil dimethylketal, and 2 parts of benzoyl peroxide.

In a preferred embodiment the system comprises a monomer and a polymer or a composite of a plurality of monomers and a polymer. The monomers are subjected to diffusion after exposure whereas the polymer forms a stationary phase, i.e. does not change position or does only change position to a minor extent. Because of the monomer diffusion upon polymerization the volume of the layer locally increases at the illuminated areas and decreases at the unexposed areas.

In FIG. 2 a LEP layer 3 is provided onto a corrugated surface 4. This can be done by spin coating or by any other known technique. The LEP can be a PEDOT-containing material. The LEP layer normally contains two distinctive layers: (1) the hole-conducting layer (PEDOT) near the ITO electrode, and (2) the electron-conducting and light-emitting layer (e.g. PPV or polyfluorene) near the cathode. The photo-embossing layer can be applied below the ITO. This layer can also be applied below the cathode but in that case the order of film forming is providing (1) a photo-embossing layer, (2) a cathode (e.g., Ba/Al, LiF, or Ca), (3) an electron-conducting layer, (4) a hole-conducting layer, and (5) the ITO. The opposite order may be used, but as the ITO is coated on glass only limited surface deformation of the LEP layer will be possible.

FIG. 3 shows a pyramid-like corrugated surface. This structure can be made by applying known ITO sputtering techniques. Top angles a of the pyramids may be vary between a broad range, for instance between 10° and 90°.

FIG. 4 shows another structure, which is more rounded-off. Such structures can easily been made by the instantly claimed embossing techniques.

1. A method for photo-embossing a monomer-containing layer for obtaining a photovoltaic cell, a light emitting diode (LED), or a light emitting electrochemical cell (LEC) by the steps of:
(a) optionally providing one or more layers onto the surface of the monomer-containing layer;
(b) irradiating through a mask a layer consisting of a homogeneous blend of at least two different compounds, at least one of which is a polymerizable monomer, to obtain a monomer-containing layer with exposed and non-exposed areas;
(c) optionally providing further layers onto the surface of the monomer-containing layer;
(d) expanding the exposed or the non-exposed areas by diffusing at least one of the monomers to the exposed areas to obtain a corrugated surface of the layer;
or interchanging steps c) and d).

2. The method according to claim 1 wherein at least a light emitting or photovoltaic organic polymer layer is provided as a layer onto the corrugated surface and areas of the monomer-containing layer are expanded by applying a heat treatment at a temperature above the Tg of the light emitting or photovoltaic organic polymer.

3. The method according to claim 1 wherein a blend of at least one polymerizable monomer and a polymer is used.

4. The method according to claim 1 wherein the monomer-containing layer further contains at least one of a polymer, a photo-initiator, and a thermal initiator.

5. The method according to claim 3 wherein the monomer is a (meth)acrylic monomer.

6. The method according to claim 1 wherein the photovoltaic cell is an organic photovoltaic cell or a hybrid organic-inorganic photovoltaic cell (Grätzel cell) and the LED is an organic LED, preferably comprising a light emitting polymer.

7. A LED or LEC comprising a substrate, superposed by a corrugated first electrode layer, superposed by a light emitting organic luminescent layer having an upper and a lower surface that follow the structure of the corrugated first electrode layer, superposed by a second electrode layer, and optionally further layers.

8. The LED or LEC of claim 7 comprising a substrate, superposed by a corrugated monomer-containing layer obtainable by the method of claim 1, superposed by a first electrode layer, superposed by a light emitting organic luminescent layer, superposed by a second electrode layer, and optionally superposed by a protective layer.

9. The LED or LEC of claim 7 wherein at least one of the layers is a reflective layer.

10. The LED or LEC of claim 7 wherein at least one of the substrate, the corrugated monomer-containing layer, the first electrode layer, the second electrode, and the optional protective layer is transparent.

11. The LED or LEC of claim 7 wherein the light emitting organic luminescent layer is a light emitting polymeric (LEP) layer having a surface area being at least 30%, preferably 50 to 100%, greater that the planar projected area thereof.

12. A photovoltaic cell comprising a substrate, superposed by a corrugated monomer-containing layer obtainable by the method of claim 1, superposed by a first electrode layer, superposed by an organic photovoltaic layer, superposed by a second electrode layer, and optionally superposed by a protective layer, wherein one of the electrodes acts as, or is equipped with, a reflective layer.
